(19) United States
(12) Patent Application Publication
(10) Pub. No.: US 2004/0227524 A1
(43) Pub. Date: Nov. 18, 2004

(54) Method and system for measuring thickness of thin films with automatic stabilization of measurement accuracy

(76) Inventors: Boris Kesil, San Jose, CA (US); Leonid Velikov, San Carlos, CA (US); Yuri Vorobyev, San Carlos, CA (US)

Correspondence Address: Boris Kesil, MultiMetrixs, LLC, 1040 Di Giulio Avenue, #160, Santa Clara, CA, 95050, US

(21) Appl. No.: 10/434,625

(22) Filed: May 12, 2003

(51) Int. Cl. G01R 27/04; G01R 27/32

(52) U.S. Cl. 324/635

(57) ABSTRACT

The system and method are based on stabilization of the distance between the sensor coil and the surface of the film being measured by constantly measuring the angle of inclination α of a tangent to the curve that represent dependence of the resonance power of the sensor-film system from the distance between the sensor and the film. The aforementioned angle is calculated plotting the resonance curve of a signal, calculating the area between the resonance curve and the abscissa axis, plotting the curve that represent dependence of the aforementioned area from the distance between the sensor coil and the film, measuring the angle α in a preselected point on the last-mentioned curve, and maintaining the distance between the sensor coil and the film constant by keeping angle α constant in a any measurement point. Angle α can be selected within the range of 0 to 90° C.

### FIELD OF THE INVENTION

The present invention relates to the field of measurement of film thickness, more specifically, to measuring thickness of conductive coatings on various conductive substrates or on non-conductive substrates with electric properties different from those of the coating films. In particular, the invention may find use in measuring thickness of coating films on semiconductor wafers, hard drive disks, or the like.

### BACKGROUND OF THE INVENTION

There exists a great variety of methods and systems used in the industry for measuring thickness of coating films and layers applied or laid onto substrates. These methods and systems can be classified in accordance with different criteria. Classification of one type divides these methods into direct and indirect.

An example of a direct method is measurement of a thickness in thin metal coating films by means of so-called X-ray reflectivity. One of these methods is based on a principle that X-rays and gamma-rays are absorbed by matter. When a beam of rays passes through a material, the amount of the beam absorbed depends on what elements the material consists of, and how much of the material the beam has to pass through. This phenomenon is used to measure the thickness or density of a material. The advantage of measuring in this way is that the gauge does not have to touch the material it is measuring. In other words, in thickness measurement, the surface of a web or strip product will not be scratched. The instrument for this method is e.g., RMS1000 Radiometric System produced by Staplethorne Ltd (UK). The instrument uses a suitable radiation source and one or more radiation detectors installed in a mechanical housing which also provides high quality radiological shielding. The source may be an X-ray tube or a radioactive source. The instrument also uses a set of beam defining collimators and one or more radiation detectors. The detectors measure the radiation absorbed within the object or flow being measured and output the signal data to a computer. For thickness gauging, the collimators usually define a single, narrow beam. This gives optimum spatial resolution.

A disadvantage of radiation methods is the use of X-ray or gamma radiation that requires special safety measures for protection of the users against the radiation. The instruments of this type are the most expensive as compared to metrological equipment of other systems.

Another example of direct measurement is a method of optical interferometry, described e.g., by I. Herman in “Optical Diagnostics for Thin Film Processing”, Academic Press, 1996, Chapter 9. Although the optical interferometry method produces the most accurate results in measuring the thickness of a coating film, it has a limitation. More specifically, for conductive films, to which the present invention pertains, this method is limited to measurement of extremely thin coating films which are thin to the extent that a nontransparent material, such as metal, functions as transparent. In other words, this method is unsuitable or is difficult to use for measuring conductive films thicker than 200 Å to 500 Å.

Another example of direct measurement methods is measuring thickness of a film in situ in the course of its formation, e.g., in sputtering, magnetron target sputtering, CVD, PVD, etc. These methods, which are also described in the aforementioned book of I. Herman, may involve the use of the aforementioned optical interferometry or ellipsometry. However, in this case measurement is carried out with reference to both the surface of the substrate and the surface of the growing layer. Therefore, this method is inapplicable to measuring thickness of the film that has been already deposited.

In view of the problems associated with direct methods, indirect non-destructive methods are more popular for measuring thickness of ready-made films. An example of a well-known non-destructive indirect method used for measuring thickness of a film is the so-called “four-point probe method”. This method is based on the use of four contacts, which are brought into physical contact with the surface of the film being measured. As a rule, all four contacts are equally spaced and arranged in line, although this is not a compulsory requirement. Detailed description of the four-point probe method can be found in “Semiconductor Material and Device Characterization” John Wiley & Sons, Inc., N.Y., 1990, pp. 2-40, by D. Schroder. The same book describes how to interpret the results of measurements. This method is classified as indirect because the results of measurement are indirectly related to the thickness of the film. It is understood that each measurement of electric characteristics has to correlated with the actual thickness of the film in each particular measurement, e.g., by cutting a sample from the object and measuring the thickness of the film in a cross-section of the sample, e.g., with the use of an optical or electron microscope. Nevertheless, in view of its simplicity, low cost, and convenience of handling, the four-point probe method is the most popular in the semiconductor industry.

However, the four-point method has some disadvantages. The main problem associated with the aforementioned four-point probe method consists in that in each measurement it is required to ensure reliable contact in each measurement point. This is difficult to achieve since conditions of contact vary from sample to sample as well as between the four pointed contact elements of the probe itself in repeated measurement with the same probe. Such non-uniformity affects the results of measurements and makes it impossible to perform precision calibration.

Known in the art are also methods for measuring film thickness with the use of inductive sensors. For example, U.S. Pat. No. 6,072,313 issued in 2000 to L. Li et al. describes in-situ monitoring and control of conductive films by detecting changes in induced eddy currents. More specifically, the change in thickness of a film on an underlying body such as a semiconductor substrate is monitored in situ by inducing a current in the film, and as the thickness of the film changes (either increase or decrease), the changes in the current are detected. With a conductive film, eddy currents are induced in the film by generating an alternating electromagnetic field with a sensor, which includes a capacitor and an inductor. The main idea of the apparatus of U.S. Pat. No. 6,072,313 consists in using a resistor and a capacitor in a parallel resonance circuit. The resonance is caused by means of an oscillator. The inductive coupling between the oscillation circuit and the Eddy current inducted in the coating is used for improving a signal/noise ratio and can be used for improving quality of measurements. In fact, this is a method well known in the radioelectronics for measuring under conditions of the electrical resonance. The above patent describes the aforementioned inductive method for measuring thickness of a film in chemical mechanical polishing (CMP).

A similar inductive method, which was used for measuring thickness of a slag, is disclosed in U.S. Pat. No. 5,781,008 issued in 1998 to J. Muller et al. The invention relates to an apparatus for measuring the thickness of a slag layer on a metal melt in a metallurgical vessel. The apparatus comprises a first inductive eddy current sensor which indicates the distance of the apparatus from the metal melt as it is moved toward the melt. A second sensor detects when the apparatus reaches a predetermined distance relative to or contacts the slag layer and triggers the inductive eddy-current sensor when such distance is attained. The sensors are arranged in a predetermined spatial relation, and the thickness of the slag layer is determined by an evaluation device, which analyzes the received signals. The apparatus permits measurement of the thickness of the slag layer without the need of additional equipment (e.g. mechanical lance movement or distance measurement).

U.S. patent application Ser. No. 954,550 filed by Boris Kesil, et al. on Sep. 17, 2001 describes a system and method for measuring thickness and thickness fluctuation in conductive coatings with sensitivity as high as several hundred Angstroms. The system consists of an inductive sensor and a proximity sensor, which are rigidly interconnected though a piezo-actuator used for displacements of the inductive sensor with respect to the surface of the object being measured. Based on the results of the operation of the proximity sensor, the inductive sensor is maintained at a constant distance from the controlled surface. Variations in the thickness of the coating film and in the distance between the inductive sensor and the coating film change the current in the inductive coil of the sensor. The inductive sensor is calibrated so that, for a predetermined object with a predetermined metal coating and thickness of the coating, variations in the amplitude of the inductive sensor current reflect fluctuations in the thickness of the coating. The distinguishing feature of the invention resides in the actuating mechanism of microdisplacements and in the measurement and control units that realize interconnection between the proximity sensor and the inductive sensor via the actuating mechanism. The actuating mechanism is a piezo actuator. Measurement of the film thickness in the submicron range becomes possible due to highly accurate dynamic stabilization of the aforementioned distance between the inductive sensor and the object. According to one embodiment, the distance is controlled optically with the use of a miniature interferometer or a fiber-optic proximity sensor, which is rigidly connected to the inductive sensor. According to another embodiment, the distance is controlled with the use of a capacitance sensor, which is also rigidly connected to the inductive sensor. To achieve a certain level of accuracy during environment temperature variations, it is recommended to provide the proximity sensor with a thermocouple for temperature control.

However, the sensor disclosed in the aforementioned patent application could not completely solve the problems associated with accurate measurement of super-thin films, e.g., of those thinner than 500 Angstroms. This is because the construction of the aforementioned sensor is limited with regard to the range of operation frequencies, i.e., the sensor cannot be used in frequencies exceeding 30 MHz. Furthermore, the system which in this apparatus is used for stabilization of the distance between the sensor and the film is rather complicated, which makes the entire system complex and expensive. But what is most important, the aforementioned complexity delays the system response in each measurement point, so that the system have low measurement efficiency and may not be suitable for used under mass production conditions.

The above problems restrict practical application of the method and apparatus of U.S. patent application Ser. No. 09/954,550 for measuring thickness of very thin films and deviations from the thickness in the aforementioned films. Furthermore, it is obvious that the aforementioned method and apparatus do not allow thickness measurement of non-conductive films. The sensor has relatively large overall dimensions and in many cases comprises a stationary measurement instrument.

In an attempt to solve the problems of the device and method disclosed in U.S. patent application Ser. No. 954,550, the applicants of the aforementioned patent application have improved the accuracy of the method and apparatus for measuring thickness of thin films. These improved method and apparatus are disclosed in U.S. patent application Ser. No. 359,378 filed by Boris Kesil, et al. on Feb. 7, 2003. The new apparatus consists of an inductive coil having specific parameters, an external AC generator operating on frequencies, e.g., from 50 MHz to 2.5 GHz, preferably from 100 MHz to 200 MHz, and a measuring instrument, such as an oscilloscope, voltmeter, etc., for measuring output of the sensor. The coil has miniature dimensions. The invention is based on the principle that inductive coil of the sensor, active resistance of the coil winding, capacitance of the inductive coil (or a separate capacitor built into the sensor's circuit), and the aforementioned AC generator form a parallel oscillating circuit. The main distinction of the sensor of the invention from all conventional devices of this type is that it operates on very high resonance frequencies or on frequencies close to very high resonance, preferably within the range of 100 to 200 MHz. In order to maintain the aforementioned high frequency range, the oscillating circuit should have specific values of inductance L (several nano-Henries) and capacitance C (several pico-Farades), and in order to provide accurate measurements, the Q-factor on the above frequencies should exceed 10. It has also been found that on such frequencies the capacitive coupling between the coil of the oscillating circuit and the virtual coil induced in the films acquires the same weight as the mutual inductance between the both coils. In other words, the system can be described in terms of inductive-capacitive interaction between the sensor and the film to be measured. The capacitive-coupling component determines new relationships between the parameters of the film, mainly the film thickness, and parameters of the resonance oscillating circuit. By measuring the parameters of the resonance oscillating circuit, it becomes possible to measure film thickness below 500 Angstroms, as well as other characteristics of the film.

However, in the apparatus of U.S. patent application Ser. No. 359,378 the methods and system for stabilization of the distance between the sensor and the surface of the film being measured remains the same as in the system of first-mentioned U.S. patent application Ser. No. 954,550, and this feature limits significant potentials of the new method and system.

The method and apparatus aimed at still further improvement of properties disclosed in aforementioned U.S. patent application Ser. No. 359,378 are described in new U.S. patent application Ser. No. ______ filed by the same applicants as in the previous application on ______. This new apparatus allows highly accurate and efficient contactless measurement of film thicknesses below 1000 Angstroms by means of a microwave resonance sensor. The apparatus consists of a special resonator unit in the form of an open-bottom cylinder, which is connected to a microwave swept frequency source via a decoupler and a matching unit installed in a waveguide that connects the resonator unit with the microwave source. The microwave generator is fed from a power supply unit through a frequency modulator that may sweep the frequency of microwaves generated by the microwave generator. All the controls can be observed with the use of a display, such as, e.g., a monitor of a personal computer, which may be connected to the microwaveguide line, e.g., via a directed branched waveguide line for directing waves reflected from the resonator, via a reflected wave detector, an amplifier, a synchronous detector, an A/D converter, and a digital voltmeter. A feedback line is going from a direct wave detector, which is installed in a line branched from the microwaveguide between the decoupler and the matching unit, to the power supply unit. The operation resonance frequency of the resonator sensor unit should be somewhere within the range of swept frequencies of the microwave generator.

In operation, the microwave generator generates electromagnetic waves in a certain sweeping range that induces in the resonator sensor unit oscillations on the resonance frequency with a Q-factor on the order of 10⁴ or higher. A distinguishing feature of the resonator of the invention is that the design parameters of the resonator unit allow to achieve the aforementioned high Q-factor without physical contact of the sensor unit with the film to be tested. As the surface of the film to be measured constitutes the inner surface of the resonator unit, even a slightest deviation in conductivity will exert a significant influence on the Q-factor. The Q-factor, in turn, defines the height of the resonance peak. As the conductivity directly related to the film thickness, it is understood that measurement of the film thickness is reduced to measurement of the resonance peak amplitudes. This means that superhigh accuracy inherent in measurement of the resonance peaks is directly applicable to the measurement of the film thickness or film thickness deviations.

However, since this resonator is a three-dimensional or special device, the measurement surface may have the minimum value on the order of several square millimeters. In such a construction the diameter of the probe practically cannot be reduced beyond the limit of about 1 mm². In other words, even though the microwave resonance sensor of the type described in U.S. patent application Ser. No. ______ is extremely accurate with regard to stabilization of the sensor-gap distance, it has limitations with regard to the lateral measurement accuracy.

### OBJECTS AND SUMMARY OF THE INVENTION

It is an object of the present invention to provide a method and system for measuring thickness of conductive films with automatic stabilization of a gap between the sensor and the film being measured, and hence for automatic stabilization of the measurement accuracy. It is another object to maintain stability of measurement in the aforementioned system on the bases of specificity in the behavior of resonance frequency in an oscillating circuit formed by the coil in the vicinity of the measured film. It is an object of the invention to provide a method and system for stabilization of the measurement without the use of complicated measurement devices for distance control. It is an object of the invention to provide the aforementioned system and method which are based on the value of the resonance generated by a combined oscillation circuit composed of the oscillation circuit of the sensor coil and a virtual oscillating circuit of the measurement film. Still another object is to stabilize the distance between the sensor and the film by processing the measurement signal that corresponds to the resonance of the sensor-film system.

The system and method of the invention are based on stabilization of the distance between the sensor coil and the surface of the film being measured by constantly measuring the angle of inclination a of a tangent to the curve that represents dependence of the resonance power of the sensor-film system from the distance between the sensor and the film. The aforementioned angle is calculated plotting the resonance curve of a signal, calculating the area between the resonance curve and the abscissa axis, plotting the curve that represents dependence of the aforementioned area from the distance between the sensor coil and the film, measuring angle α in a preselected point on the last-mentioned curve, and maintaining the distance between the sensor coil and the film constant by keeping angle α constant in any measurement point. Angle α can be selected within the range of 0 to 90° C.

### BRIEF DESCRIPTION OF THE DRAWINGS

FIG. 1 is a schematic view of a known inductive sensor used, e.g., for positioning an inductive sensor relative to the surface of an object.

FIG. 2 is a simplified model of the sensor of FIG. 1.

FIG. 3 is further simplification of the model of FIG. 2.

FIG. 4 is a schematic presentation of the equivalent circuit of a “sensor-film” system of the present invention in the form of two coupled oscillating circuits that include the oscillating circuit of the sensor coil and a virtual oscillating circuit of the film.

FIG. 5 is a schematic view of the system of the invention.

FIG. 6 is a curve that shows frequency-amplitude characteristics of the resonance signal in the sensor-film system presented by the voltage-versus-frequency curve.

FIG. 7 is a curve that shows dependence of the resonance signal power from the measurement distance, this curve being used for calculating the angle of tangent to the point on the curve, the angle beings used as a characteristic parameter for stabilization of the measurement distance.

### DETAILED DESCRIPTION OF THE INVENTION

Generally speaking, all inductive sensors are based on the principle that in its simplest form an inductive sensor comprises a conductive coil, which is located in close proximity to a conductive film to be measured and in which an electric current is induced. The conductive film can be considered as a short-circuited virtual coil turn with a predetermined electrical resistance. Since a mutual inductance exists between the aforementioned conductive coil and the virtual coil turn, an electric current is generated in the virtual coil turn. This current is known as eddy current or Foucault current. Resistance of the virtual coil turn, which depends on the material of the conductive film and, naturally, on its thickness, influences the amplitude of the alternating current induced in the virtual turn. It is understood that the amplitude of the aforementioned current will depend also on the thickness of the conductive film.

However, realization of a method and system based on the above principle in application to thin films is not obvious. This is because such realization would involve a number of important variable parameters which depend on a specific mode of realization and which are interrelated so that their relationships not always can be realized in a practical device.

In order to substantiate the above statement, let us consider the construction of an inductive sensor of the aforementioned type in more detail.

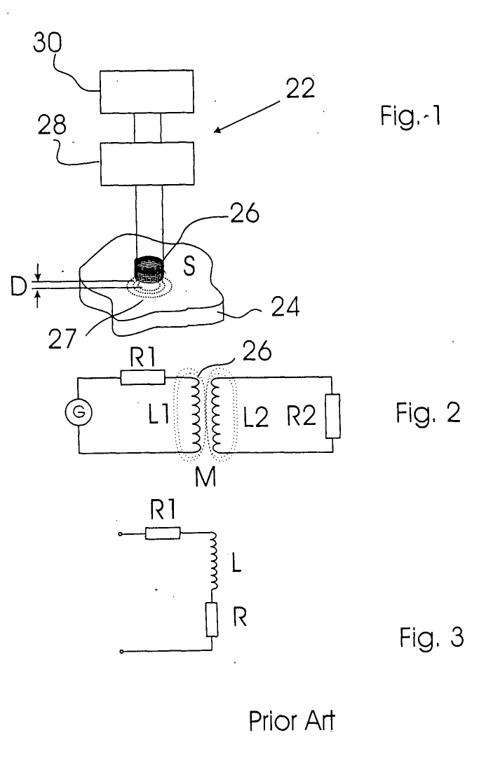

FIG. 1 is a schematic view of a known inductive sensor used, e.g., for positioning of an inductive sensor 22′ relative to the surface S′ of an object 24′. Let us assume that the surface S′ of the object 24′ is conductive. The inductive sensor comprises an electromagnetic coil 26′ connected to an electronic unit 28′, which, in turn, is connected to a signal processing unit 30′. The latter can be connected, e.g., to a computer (not shown). The electronic unit 28′ may contain a signal oscillator (not shown), which induces in the electromagnetic coil 26′ an alternating current with a frequency within the range from several kHz to several hundred KHz. In FIG. 1, symbol D designates the distance between the electromagnetic coil 26′ and the surface S.

In a simplified form, the sensor of FIG. 1 can be represented by a model shown in FIG. 2. In this model, L1 designates inductance of the electromagnetic coil 26′; R1 designates resistance of the coil 26′; L2 designates inductance of the aforementioned virtual coil turn 27′ (FIG. 1); and R2 is electrical resistance of the aforementioned virtual coil turn 27′. M designates mutual induction between L1 and L2.

It can be seen from the model of FIG. 2 that the amplitude of current I generated in coil 26′ will depend on R1, L1, L2, R2 and M. It is also understood that in this influence M is the most important parameter since it directly depends on the distance D (FIG. 1) from the inductive sensor 22′ to the surface S.

FIG. 3 is further simplification of the model of FIG. 2. Parameters L and R are functions that can be expressed in terms of L1, L2, M, R1, and R2. Therefore, as shown in FIG. 3, these parameters can be considered as functions L(D) and R(D), where D is the aforementioned distance (FIG. 1).

The model of FIG. 3 can also be characterized by a quality factor Q, which is directly proportional to the frequency of the current in the sensor coil 26′, to inductance of the sensor of FIG. 3, and is inversely proportional to a distance D (FIG. 1) from the sensor coil 26′ to the surface S. The higher is the value of Q, the higher is stability of the measurement system and the higher is the measuring accuracy. Thus it is clear that in order to achieve a higher value of Q, it is necessary to operate on higher frequencies of the alternating currents in the inductance coil 26′. Analysis of relationships between Q, L, and R for a fixed distance D was made by S. Roach in article “Designing and Building an Eddy Current Position Sensor” at http://www.sensormag.com/articles/0998/edd0998/main.shtml. S. Roach introduces an important parameter, i.e., a ratio of D to the diameter of the sensor coil 26′, and shows that R does not practically depend on the above ratio, while the increase of this parameter leads to the growth in L and Q. When distance D becomes equal approximately to the diameter of the coil 26′, all three parameters, i.e., L, Q, and R are stabilized, i.e., further increase in the distance practically does not change these parameters. In his important work, S. Roach generalized the relationships between the aforementioned parameters and showed that, irrespective of actual dimensions of the sensor, “the rapid loss of sensitivity with distance strictly limits the range of eddy current sensor to about ½ the coil diameter and constitutes the most important limitation of this type of sensing”.

The impedance of the coil also depends on such factors as film thickness, flatness of the film, transverse dimensions, temperature of the film and coil, coil geometry and DC resistance, operating frequency, magnetic and electric properties of the film, etc.

As far as the operating frequency of the inductive coil is concerned, the sensor possesses a self-resonance frequency, which is generated by an oscillating circuit formed by the power-supply cable and the capacitor. As has been shown by S. Roach, in order to improve sensitivity, it is recommended to increase the quality factor Q and hence the frequency. However, the sensor must operate on frequencies at least a factor of three below the self-resonant frequency. Thus, practical frequency values for air core coils typically lie between 10 kHz and 10 MHz.

The depth of penetration of the electromagnetic field into the conductive film is also important for understanding the principle of operation of an inductive sensor. It is known that when an alternating electromagnetic field propagates from non-conductive medium into a conductive medium, it is dampened according to an exponential law. For the case of propagation through the flat interface, electric and magnetic components of the alternating electromagnetic field can be expressed by the following formulae:

E=E₀ exp(−αx)

H=H₀ exp(−αx),

where α=(πfμ₀μσ_{DC})^{1/2}, f is oscillation frequency of the electromagnetic field, σ_{DC} is conductivity of the medium measured on direct current, and μ₀=1.26×10⁻⁶ H/m (for non-magnetic materials μ=1).

Distance x from the interface, which is equal to

x=δ=1/α=1/(πfμ₀σ_{DC})^{1/2} (1a)

and at which the amplitude of the electromagnetic wave decreases by e times, is called the depth of penetration or a skin layer thickness. Based on formula (1a), for copper on frequency of 10 kHz the skin depth δ is equal approximately to 650 μm, on frequency of 100 kHz to 200 μm, on frequency of 1 MHz to 65 μm, on frequency of 10 MHz to 20 μm, on frequency 100 MHz to 6.5 μm, and on frequency 10 GHz to 0.65 μm.

The above values show that for the films used in the semiconductor industry, which are typically with the thickness on the order of 1 μm or thinner, the electromagnetic field can be considered practically as uniform. This is because on any frequency in the range from 10 KHz to 10 MHz the electromagnetic waves begin to dampen on much greater depth than the thickness of the aforementioned films. It is only on frequencies substantially greater than 100 MHz (e.g., 10 GHz), the depth of penetration of the electromagnetic fields becomes comparable with the thickness of the film.

Similar trend is observed in the films made from other metals, where the skin layer is even thicker because of lower conductivity. At the same time, deviations from uniformity in the thickness of the conductive coating films used in the semiconductor industry, e.g., copper or aluminum layers on the surface of silicon substrates, should not exceed 5%, and in some cases 2% of the average thickness of the layer. In other words, the deviations should be measured in hundreds of Angstroms. It is understood that conventional inductive sensors of the types described above and used in a conventional manner are inapplicable for the solution of the above problem. Furthermore, in order to match conditions of semiconductor production, such sensors must have miniature constructions in order to be installed in close proximity to the measurement site. The distance between the measurement element of the inductive sensor and the surface of the film being measured also becomes a critical issue. Due to high sensitivity, the sensor becomes very sensitive to the influence of the environment, especially, mechanical vibrations, variations in temperature, etc.

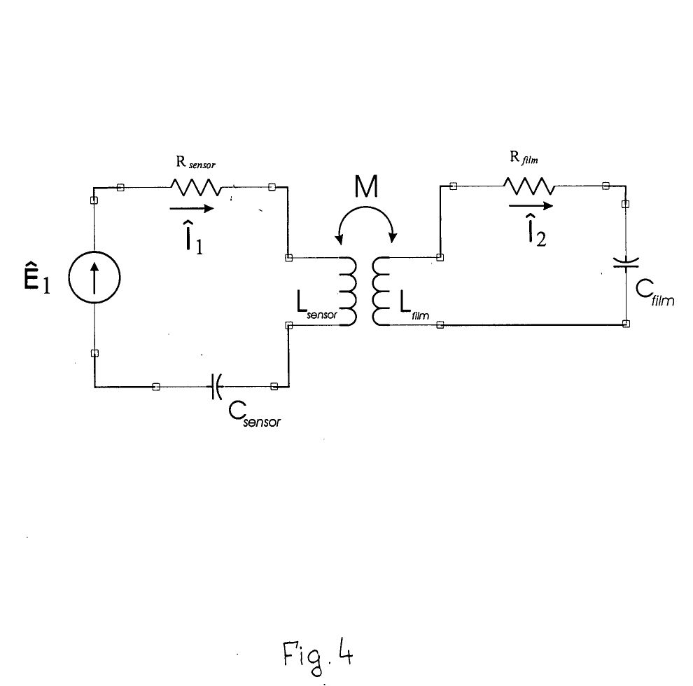

Keeping in mind the aforementioned explanation of operation principles of inductive sensors, let us consider a process of measurement of a conductive film on the surface of a substrate with reference to a “sensor-film” system 40, which in a schematic form is shown in FIG. 4 and which is used as a basis for the method and system of the present invention. In principle, the system of FIG. 4 is similar to the model shown in the aforementioned U.S. patent application Ser. No. 359,378.

It can be seen from FIG. 4, that the equivalent “sensor-film” system of the present invention may be presented as a pair of two inductively coupled oscillation circuits 42 and 44. The first oscillating circuit 42 is the same sensor oscillating circuit as that described in FIG. 2 and comprises a closed-loop circuit composed of the components connected in series and equivalent to the following parameters: inherent inductance Lₛₑₙₛₒᵣ of a coil 46, an active resistance Rₛₑₙₛₒᵣ of the coil 46, an inherent capacitance Cₛₑₙₛₒᵣ of the coil 46, and electromotive force Ê₁ (hereinafter referred to as EMF Ê₁) of an external a.c. generator (not shown).

The second oscillating circuit 44, i.e., the aforementioned virtual coil circuit, comprises a closed-loop circuit composed of the components connected in series and equivalent to the following parameters: inherent inductance L_{film} of a virtual coil 48 formed by the film, an active resistance R_{film} of the film virtual coil 48, and an inherent capacitance C_{film} of the film virtual coil 48.

It is obvious that the sensor coil 46 of the aforementioned coupled electric circuit generates an electromagnetic field that surrounds this coil. If a conductive film, which in FIG. 4 is represented by the virtual film coil 48, is absent or is spaced from the sensor coil 46 at a significant distance, the magnetic lines of the field will be closed in space, and under such conditions the oscillating circuit 42 may tune only to the inherent resonance of the sensor coil 46. In this case we have a non-coupled closed electric circuit, which is the left oscillating circuit of the system shown in FIG. 4. In other words, in this case the film-side oscillating circuit (the right side of the system of FIG. 4) does not exists.

As the sensor 46 approaches the conductive film, i.e., the virtual film coil 48, e.g., on a semiconductor substrate (not shown), at some moment the magnetic flow of the sensor coil 46 begins to interact with a magnetic flow induced in the film coil 48 under the sensor coil 46. This interaction will cause a bias in the resonance frequency of the sensor coil 46, and this bias will correspond to the value of a complex coupling impedance of the system of FIG. 4.

Strictly speaking, in the system of FIG. 4 we have an inductive-capacitive coupling between the sensor coil 46 and the virtual “film coil” (hereinafter referred to simply as “film coil”).

For simplicity of description, let us consider only the inductive coupling between the sensor 46 and the conductive film coil 48. A common feature of inductive and capacitive couplings is that amplitude-frequency characteristics of the inductively-coupled circuits and of capacitively-coupled circuits are the same.

In inductively-coupled system of the first-mentioned type, it is possible to change the resonance frequency of the sensor oscillation circuit 42, as well as the magnitude of the coupling between the sensor coil 46 and the film coil 48. As the currents of the sensor coil 46 and the currents induced in the film coil 48 are directed towards each other, the coils have currents that flow in the opposite directions (FIG. 4).

In this case, equation of the second Kirchhoff's law can be written as follows:

Ê₁=Î₁Zₛₑₙₛₒᵣ−Î₂Z_{coupling} (1)

Î₂Z_{film}−Î₁Z_{coupling}=0, (2)

where Zₛₑₙₛₒᵣ=Rₛₑₙₛₒᵣ+jX₁ is a complex impedance of the sensor coil circuit, Z_{film}=R_{film}+jX₂ is a complex impedance of the virtual “film oscillating circuit”, and Z_{coupling}=jwM is a coupling impedance.

It would be convenient to introduce some new definitions, which are the following:

Z²_{introduced1}=Z_{coupling}/Z_{film}—complex impedance introduced into the first circuit, i.e., the sensor oscillating circuit 42, and

Z²_{introduced2}=Z_{coupling}/Zₛₑₙₛₒᵣ—complex impedance introduced into the second, i.e., virtual “film oscillating circuit” 44.

Let us assume the following:

Z_{introduced1}=R_{introduced1}+jX_{introduced1} and

Z_{introduced2}=R_{introduced2}+jX_{introduced2} (3)

Let us solve the system of the equations for currents:

Î₂=Î₁/(Z_{coupling}/Zₛₑₙₛₒᵣ) and Î₂=Ê₁/[Zₛₑₙₛₒᵣ−(Z²_{coupling}/Z_{film})]). (4)

If the frequency of the input electromotive force Ê₁ varies approximately from 0 to 100 MHz, then the following resonances may take place in the “sensor-film” system:

The first specific resonance will occur at frequency ω, under the following condition:

X₁+jX_{introduced1}=0. (5)

In this case, currents I₁ [symbol] I₂ will be at their maximum and will be equal to:

I₁ₚₑₐₖ=E₁/(Rₛₑₙₛₒᵣ+R_{introduced1}) (6)

I₂ₚₑₐₖ=E₁*[(Z_{coupling}/_Z_{film})]/(Rₛₑₙₛₒᵣ+R_{introduced1}) (7)

The second specific resonance will occur at frequency ω under the following condition:

X₂+X_{introduced2}=0 (8)

In this case, the currents will also be at their maximum:

I₁ₚₑₐₖ=E₁*[(Z_{film}/Zₛₑₙₛₒᵣ)]/(R_{film}+R_{introduced2}); (9)

I₂ₚₑₐₖ=E₁*[(Z_{coupling}/_Z_{film})]/(R_{film}+R_{introduced2}) (10)

Under the complex impedance conditions, the current I₂ₚₑₐₖ should be chosen so as to satisfy the following condition:

I₁ₘₐₓₚₑₐₖ=E₁/2 Rₛₑₙₛₒᵣ; I₂ₘₐₓₚₑₐₖ=E₁/2(Rₛₑₙₛₒᵣ*R_{film})^{1/2} (11).

Complete resonance in the “sensor-film” system occurs when the following two conditions are satisfied:

X₁=X₂=0 (12)

I₁ₘₐₓₚₑₐₖ=E₁/2 Rₛₑₙₛₒᵣ; Iₛₑₙₛₒᵣₘₐₓₚₑₐₖ=E₁/2(Rₛₑₙₛₒᵣ*R_{film})^{1/2} (13)

For complex resonance, however, coupling should have a magnitude which Zₛₑₙₛₒᵣ/Rₛₑₙₛₒᵣ times greater than that for the complete resonance.

Let us consider the amplitude-frequency characteristic of the inductive coupling between the sensor coil 46 and the film coil 48. Such characteristic can be expressed by the relationship between the current I₂ generated in the film coil 48 and the frequency ω or the so-called common imbalance ε, which is defined below. Since in the system of FIG. 4 the sensor coil circuit 42 and the film coil circuit 44 are not the same, let us assume for simplicity of understanding, that both circuits are identical. The following expression can be written for this condition:

Zₛₑₙₛₒᵣ=Z_{film}=Z=R(1+jε), (14)

wherefrom the aforementioned common imbalance ε is determined as a ratio ε=X/R.

Q factor is Q=ω_{π}·L/R, and the coefficient of proportionality k for identical oscillation circuits (Lₛₑₙₛₒᵣ=L_{film}=L) is equal to M/L. Let us introduce a ratio X_{M}/R. Based on the previous statement, this ratio can be expressed as follows:

X_{M}/R=ω_{π}·M/R·ω_{π}L/ω_{π}L=M/L·ω_{π}L/R=kQ (15)

The maximal current that can be induced in the virtual film coil for the case of identical oscillating circuits (Rₛₑₙₛₒᵣ=R_{film}=R) is equal to

I_{filmmax}=E₁/2R (16)

The rated frequency-amplitude characteristic of the coupled oscillating circuits can be expressed as follows:

$$\frac{{I}_{sensor}}{{I}_{sensormax}} = \frac{2 kQ}{\sqrt{{[ 1 + {( kQ )}^{2} - {ϵ}^{2} ]}^{2} + {4}^{{ϵ}^{\hat{2}}}}} . \qquad ( 17 )$$

where 2 kQ is a coefficient of coupling, the value of which characterizes the mode of operation of the sensor-film system. The meaning of this coefficient will be better understood after considering the explanation given below.

If the coefficient of coupling is low (“weak coupling”), i.e., kQ<<1, then the value of kQ² can be neglected, and the expression of formula (17) can be simplified to the form of equation (18):

$$\frac{{I}_{sensor}}{{I}_{sensormax}} = \frac{2 k Q}{1 + {ϵ}^{2}} \qquad ( 18 )$$

In this case, the complete resonance cannot be achieved. In an actual system, this condition may exist when the film to be measured is located in a position remote from the coil sensor, in other words, at a distance, at which the coupling exists but in a very weak form. The critical condition will exist at so-called critical coupling (kQ=1), which can be expressed as follows:

$$\frac{{I}_{sensor}}{{I}_{sensormax}} = \frac{2}{\sqrt{4 {+}^{{ϵ}^{4}}}} \qquad ( 19 )$$

The frequency-amplitude characteristic has maximum at ε=0.

When the coupling is “strong”, i.e., kQ>1, the system may develop the combined, or so-called complex resonance. In this case, the frequency-amplitude characteristic will have two maximums. Thus, as the coefficient of coupling of kQ increases, the picture of the frequency-amplitude characteristic will transfer from a single-resonance shape to a double-resonance shape.

Thus, under conditions of weak coupling, the current maximum occurs on frequency ω_{π}, while under conditions of strong coupling the current curve will have two peaks on frequencies determined from the following equation:

$${ω}_{max 1 , max 2} = \frac{{ω}_{π}}{\sqrt{1 \pm \sqrt{{k}^{2} - {b}^{2}}}} , \qquad ( 20 )$$

where b=1/Q.

For the sake of simplicity, the coil-film system was considered for the case when the coil oscillating circuit and the virtual film oscillating circuit are identical. The actual coil-film system will be to some extent different in that under conditions of weak coupling the resonance of the system (the first partial resonance) will decompose into two partial resonances. One of these two partial resonance will correspond to the partial resonance of the sensor coil, and the second will correspond to the partial resonance of the film.

When the coil-film system operates in the range from the aforementioned critical-coupling conditions to the strong-coupling condition, the resonance pattern may vary from complex to complete resonance.

In an actual film-thickness measurement procedure, the transfer from the one-peak shape to the two-peak shape will occur when the sensor approaches the film from a remote position to a close-proximity position. In fact, in the course measurement, one can observe all four types of resonances, i.e., the first partial resonance, the second partial resonance, the complex resonance, and the complete resonance.

In practice, however, the aforementioned resonances cannot be always distinctly distinguished. This is because the oscillating circuits of the coil circuit and of the virtual film circuit may be significantly different depending on such factors as parameters of the oscillating circuits per se, the coefficient of coupling (magnitude of the gap), power (amplitude) of the a.c. generator signal, location of measurement point, etc. In reality, we will have a common or resulting resonance, in which the share of all aforementioned components will depend on all variable factors listed above.

It should be noted that during measurement the parameters of the coil oscillating circuit (sensor circuit) always remain unchanged, so that the complex impedance of the system will depend only on the distance from the sensor to the film being measured, as well as on the film properties.

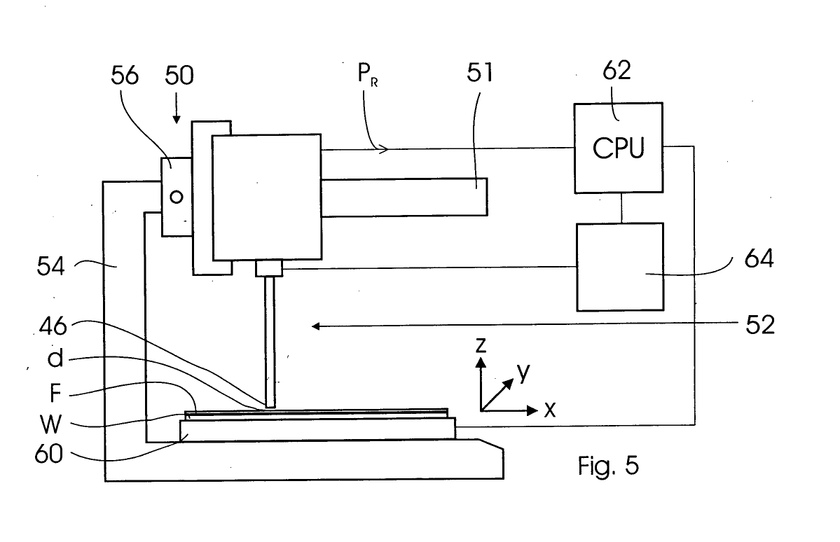

In an actual construction of the apparatus used in the distance stabilization system of the invention, which is shown in FIG. 5, the measurement head 50 that contains the components of the coil oscillating circuit 42 (FIG. 4), including the aforementioned inductive coil 46 attached to the tip of the measurement rod 52, an a.c. generator with a modulator, etc., is supported by the mounting frame 54. Position of the sensor coil 46 relative to the mounting frame 54 can be adjusted by means of a micro-adjustment mechanism, e.g., a screw 56 for rough adjustment in the vertical direction and by a piezo actuator 58 for fine tuning of the vertical position. With the use of the piezo actuator, accuracy of micro-adjustment for positioning the tip of the rod 52 and hence of the sensor coil 46 with respect to the surface of the film F may be as small as 1 micron, or less. The distance D between the tip of the rod 52 and the surface of the film F may be within the range of about 10 to 100 microns. In addition to the vertical movement (axis Z), the measurement head 50 can be driven in a horizontal direction (axis X), e.g., by means of a pinion-and-rack mechanism 51. In order to provide measurement in any point of the film F, the object, e.g., a semiconductor wafer W is supported by a rotating platform 60.

All motions and measurement operations are controlled from a central processing unit (CPU) 62, which receives signals from the a.c. generator (not shown) and is connected to drives of the vertical, horizontal motions of the measurement head 50, as well as to rotary drive of the platform 60 and to the power supply 64 of the piezo actuator 58.

Let us consider operation of the apparatus of FIG. 5 in the system for measuring the thickness of a conductive film F applied onto the surface of a semiconductor substrate W. The substrate W with the film F to be measured is installed and fixed on the rotating platform 60. The measurement head 50 is then approached towards the film with the use of the screw 56 for rough adjustment, and then by the piezo actuator 58 for fine tuning of the vertical position of the senor coil 46 relative to the surface of the film F. Position of the measurement point in the horizontal direction is adjusted by means of the pinion-and-rack mechanism 51 in combination with rotation of the platform 60. The aforementioned movement of the sensor coil 46 in the horizontal plane should be carried out with positioning accuracy of several microns. This can be achieved with the use of a known precision positioning mechanism such as step motors that can be controlled by means of the CPU 62.

The exact distance “d” between the sensor coil 46 and the surface of the film F is established and stabilized as described below.

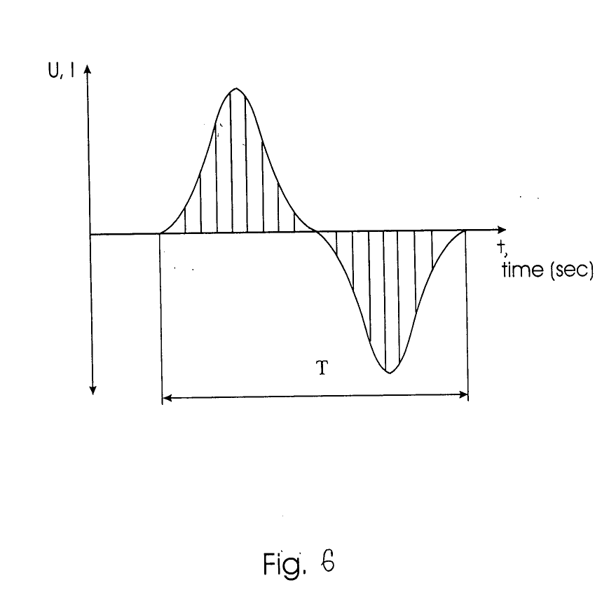

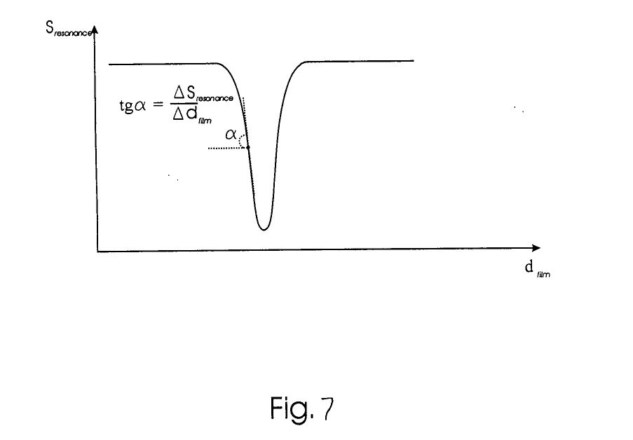

The procedure of excitation of the coil sensor 46 is described in detail in aforementioned U.S. patent application Ser. No. (2^{nd} application) ______ of the same applicants. The generator-modulator unit located in the measuring head 50 generates a voltage signal having a carrier frequency of 50 to 200 MHz and modulated by a voltage signal with the frequency in the range of 400 Hz to 20 KHz. The modulated carrier signal is supplied to the sensor coil 46 and is tuned to the resonance of the sensor coil oscillating circuit 42. In FIG. 4 the aforementioned modulated signal is presented by symbol Ê₁. The measurement signal is an amplified resonance signal P_{R} (FIG. 5), which is sent to the CPU 62. In general, the aforementioned signal may represent frequency-amplitude characteristics, such as voltage versus frequency, current versus frequency, or power versus frequency of the combined oscillating circuit formed by the sensor-film system shown in FIG. 4. Let us consider, for the sake of example, the frequency-amplitude characteristics presented by the voltage-versus-frequency curve, which is shown in FIG. 6. In fact, this graph of FIG. 6 is development of the resonance frequency signal generated by the sensor-film system of FIG. 4 and observed on an oscilloscope (not shown). As can be seen from FIG. 6, the measurement signal has a shape of a periodic function, which can be described by a Fourier series. The shape shown in FIG. 6 is a typical one but in reality may be distorted. The area between the curve K and the abscissa axis t (the hatched area in FIG. 6) is considered as a parameter that characterizes the power of resonance (S_{resonsnce}) of the measurement signal during period T. The aforementioned area is calculated by the CPU 62. it is understood that depending on the distance “d”, the power of the resonance signal S_{resonsnce} and hence the aforementioned area will vary. This dependence is shown in FIG. 7, which is “d” versus S_{resonsnce} curve. Such measurements are carried out and registered by the CPU 62 in each fixed measurement point of the step-by-step movement performed by the measurement head 50 under control of the aforementioned piezo actuator 58. The aforementioned step-by-step downward movement toward the film is accompanied by variations in the resonance pattern with transfer from the first partial resonance mode to the complete resonance mode, as has been described above. Although the system of the invention will work in any resonance mode, it is more advantageous to operate in the complete resonance mode, which provides the highest accuracy.

The applicants have found that the most convenient method for stabilization of distance “d” is to constantly measure the angle of inclination α (FIG. 7) of a tangent to the function curve of FIG. 7 and to adjust the precise vertical position of the sensor coil 46 relative to the surface of the film for maintaining angle α constant in any measurement point. Position of the point on the curve where the angle of the tangent is measured is arbitrary for the first measurement cycle and is assumed as a reference for the subsequent measurement points.

Thus, the method of the invention for stabilization of the distance “d” consists of continuously measuring angle α on the aforementioned curve of FIG. 7 and maintaining this angle constant by adjusting distance “d” with the use of the piezo-actuator 52. It is understood that the simple step of stabilization described in the previous sentence, in turn, is based on the phenomenon of the complex resonance that occurs in the sensor-film system with the virtual oscillating circuit formed by the film, when the film is located in close proximity to the sensor coil.

As has been mentioned above, angle α is selected arbitrarily by the operator and may be within the range of 0 to 90° C. After the angle is chosen, its value is inputted to the CPU 62 and is used as a staring and reference point of distance measurements. This is because, as has been shown above, angle α is in rigid correlation with the value of the distance “d”. It is known that a semiconductor substrate practically always has some sagging, which may reach 30 to 50 μm. However, in spite of such sagging, the system of the invention will always stabilize the distance “d”, as the absolute value of this distance is always maintained constant, irrespective of the position of the substrate. In other words, the sensor traces the surface of the film and follows it in a continuous mode with resolution of the stepper-motor steps.

Thus, the sequence of operation of the system shown in FIG. 4 can be summarized as follows:

1. Finding approximate value of the resonance in the sensor-film system.

2. Finding an approximate distance at which the full resonance can be achieved.

3. Selecting appropriate angle α and inputting the value of this angle into the CPU.

4. “Scanning” the surface of the film from one measurement point to the next measurement point with stabilization of angler α in each point.

The description given above relates to the case when the sensor coil and the virtual film coil have a magnetic coupling. However, in a real situation and particularly in the range of high frequencies the aforementioned sensor-film system has not only the magnetic coupling but also a capacitive coupling between the coils. This is especially true for measuring non-conductive or poorly-conductive films.

It has been found that frequency-amplitude characteristics of the system with a capacitive coupling are essentially the same as of the system with an inductive coupling described above, with the difference that instead of the mutual inductance M the capacitive sensor-film system is characterized by the capacitive coupling C_{sensor-film}. In the range of the operation frequencies of the system of the invention, both inductive and capacitive couplings play the same roles and always coexist. However, consideration of the complete system with the inductive and capacitive coupling components will require the use of extremely cumbersome formulae, although the structure of the formulae and the conclusions will be the same. In other words, the inductive-capacitive coupling will be characterized by the same modes as described for the merely inductive version. Therefore the methodology of the positioning and the structure of the system will remain the same.

It has been shown that the invention provides a method and system for measuring thickness of conductive films with automatic stabilization of a gap between the sensor and the film being measured, and hence for automatic stabilization of the measurement accuracy. The method and system of the invention maintain stability of measurement in the aforementioned system on the bases of specificity in the behavior of resonance frequency in an oscillating circuit formed by the coil in the vicinity of the measured film. The method and system of the invention stabilize the measurement without the use of complicated measurement devices for distance control but directly via feedback from each measured resonance signal of the coil-film system. It was shown that the invention is based on the value of the resonance generated by a combined oscillation circuit composed of the oscillation circuit of the sensor coil and a virtual oscillating circuit of the measurement film.

Although the invention has been shown and described with reference to specific embodiments, it is understood that these embodiments should not be construed as limiting the areas of application of the invention and that any changes and modifications are possible, provided these changes and modifications do not depart from the scope of the attached patent claims. For example, the sensors may be of any dimensions and type suitable for the system of the invention. The measurement films may be of any materials and thickness, provided the film inductively or capacitively interacts with the sensor coil. Mechanisms of movements in the direction of X, Z axes, as well as the rotation may have different drives, provided the positioning accuracy is achieved. The vertical movement may be continues instead of discrete. The actuator may be of other types than the piezo-actuator.

1. A method for measuring thickness of a thin film on a substrate with automatic stabilization of measurement accuracy, comprising:
providing a measurement system comprising an oscillating circuit that contains a sensor coil;
approaching said coil sensor toward said thin film until the distance between said sensor coil and said thin film provides interaction of said thin film with said sensor coil to form a combined sensor-film system with a sensor-film system resonance, said sensor-film system resonance being characterized by a resonance signal of said sensor-film system;
determining said resonance signal of said sensor-film system in terms of a resonance signal power;
determining dependence of said resonance signal power from said distance; and
stabilizing said distance by maintaining said dependence constant during said measuring.

2. The method of claim 1, wherein said step of determining said resonance signal of said sensor-film system in terms of a resonance signal power comprises the steps of:
presenting said resonance signal as a voltage-versus-frequency curve in the form of a periodic function in a first two-axes coordinate system with a first axis as a time of a signal period and a second axis as a signal value;
calculating said resonance signal power as the area between said curve and said second axis;
presenting said dependence of said resonance signal power from said distance in the form of a power-versus distance curve in a second two-axes coordinate system with a first axis as said area and a second axis as said distance;
selecting an arbitrary point on said power-versus distance curve;
determining an angle of inclination of a tangent to said power-versus distance curve in said arbitrary point;
constantly measuring said angle during measuring said thickness; and
carrying out said step of stabilizing by maintaining said angle constant during measuring said thickness.

3. The method of claim 2, wherein said sensor-film system comprises a resonance oscillating circuit of said sensor coil and a virtual oscillating circuit formed by said thin film spaced from said sensor coil at said distance, said distance providing interaction between said thin film and said sensor coil.

4. The method of claim 3, wherein said sensor-film resonance has a full-resonance value and wherein said step of approaching said coil sensor toward said thin film is continued unit said full-resonance value is achieved.

5. The method of claim 1, wherein said step of measuring said thickness is carried in a plurality of measurement points and wherein said steps of stabilizing by maintaining said angle constant is carried out in each measurement out of said plurality and by measuring said angle in said arbitrary point in said each measurement point.

6. The method of claim 2, wherein said step of measuring said thickness is carried in a plurality of measurement points and wherein said steps of stabilizing by maintaining said angle constant is carried out in each point of said plurality and by measuring said angle in said arbitrary point in said each point.

7. The method of claim 4, wherein said step of measuring said thickness is carried in a plurality of measurement points and wherein said steps of stabilizing by maintaining said angle constant is carried out in each point of said plurality and by measuring said angle in said arbitrary point in said each point.

8. The method of claim 1, wherein said interaction is a combination of an inductive coupling and a capacitive coupling.

9. The method of claim 2, wherein said interaction is a combination of an inductive coupling and a capacitive coupling.

10. The method of claim 4, wherein said interaction is a combination of an inductive coupling and a capacitive coupling.

11. The method of claim 5, wherein said interaction is a combination of an inductive coupling and a capacitive coupling.

12. The method of claim 7, wherein said interaction is a combination of an inductive coupling and a capacitive coupling.

13. The method of claim 1, wherein said measurement system has means for controlling said distance via feedback from each said resonance signal of said coil-film system and without the use of a distance measurement means, said sensor coil combining two functions one of which is generation of resonance in said sensor-film system and another one is carrying out said step of stabilizing said distance.

14. The method of claim 13, where said means for controlling said distance is selected from the group consisting of a step motor and piezo-actuator.

15. The method of claim 14, wherein said step of determining said resonance signal of said sensor-film system in terms of a resonance signal power comprises the steps of:
presenting said resonance signal as a voltage-versus-frequency curve in the form of a periodic function in a first two-axes coordinate system with a first axis as a time of a signal period and a second axis as a signal value;
calculating said resonance signal power as the area between said curve and said second axis;
presenting said dependence of said resonance signal power from said distance in the form of a power-versus distance curve in a second two-axes coordinate system with a first axis as said area and a second axis as said distance;
selecting an arbitrary point on said power-versus distance curve;
determining an angle of inclination of a tangent to said power-versus distance curve in said arbitrary point, said controlling said distance via feedback comprises said steps of constantly measuring said angle during measuring said thickness and maintaining said angle constant during measuring said thickness.

16. The method of claim 15, wherein said sensor-film system comprises a resonance oscillating circuit of said sensor coil and a virtual oscillating circuit formed by said thin film spaced from said sensor coil at said distance, said distance providing interaction between said thin film and said sensor coil.

17. The method of claim 16, wherein said sensor-film resonance has a full-resonance value and wherein said step of approaching said coil sensor toward said thin film is continued unit said full-resonance value is achieved.

18. The method of claim 15, wherein said step of measuring said thickness is carried in a plurality of measurement points and wherein said steps of stabilizing by maintaining said angle constant is carried out in each measurement out of said plurality and by measuring said angle in said arbitrary point in said each measurement point.

19. The method of claim 15, wherein said interaction is a combination of an inductive coupling and a capacitive coupling.

20. The method of claim 18, wherein said interaction is a combination of an inductive coupling and a capacitive coupling.

21. The method of claim 1, wherein said film is a conductive film and said substrate is a semiconductor substrate.

22. The method of claim 3, wherein said film is a conductive film and said substrate is a semiconductor substrate.

23. The method of claim 5, wherein said film is a conductive film and said substrate is a semiconductor substrate.

24. The method of claim 7, wherein said film is a conductive film and said substrate is a semiconductor substrate.

25. The method of claim 15, wherein said film is a conductive film and said substrate is a semiconductor substrate.

26. A system for measuring thickness of a thin film on a substrate with automatic stabilization of measurement accuracy, comprising:
a combined resonance oscillating circuit comprising a sensor-film system composed of first oscillating circuit that contains a sensor coil and a virtual oscillating circuit which is formed by said thin film and is capable of interacting with said sensor coil, said sensor-film system generating a sensor-film system resonance which is characterized by a resonance signal of said sensor-film system;
means for moving said sensor coil with respect to said thin film for establishing a distance between said sensor coil and said thin film; and
combined means for generating said sensor-film system resonance and for stabilizing said distance during measuring said thickness.

27. The system of claim 26, wherein said combined means is said sensor coil, which stabilizes said distance without the use of distance measurement means.

28. The system of claim 27, further comprising a central processing units connected to said coil-film system for determining said sensor-film resonance in terms of a resonance signal power, presenting said resonance signal as a voltage-versus-frequency curve in the form of a periodic function in a first two-axes coordinate system with a first axis as a time of a signal period and a second axis as a signal value, calculating said resonance signal power as the area between said curve and said second axis, presenting said dependence of said resonance signal power from said distance in the form of a power-versus distance curve in a second two-axes coordinate system with a first axis as said area and a second axis as said distance, selecting an arbitrary point on said power-versus distance curve, determining an angle of inclination of a tangent to said power-versus distance curve in said arbitrary point, constantly measuring said angle during measuring said thickness, and stabilizing said angle by keeping it constant during measuring said thickness.
